(19) United States
(12) Patent Application Publication
(10) Pub. No.: US 2020/0201504 A1
(43) Pub. Date: Jun. 25, 2020

(54) SMART SENSING SYSTEM USING PRESSURE SENSOR

(71) Applicant: ELSSEN Inc., Daejeon (KR)

(72) Inventor: Ji Man PARK, Daejeon (KR)

(21) Appl. No.: 16/377,835

(22) Filed: Apr. 8, 2019

(30) Foreign Application Priority Data
Dec. 24, 2018 (KR) 10-2018-0168426

(51) Int. Cl. G06F 3/041; H03K 17/96; G06F 3/045

(52) U.S. Cl. CPC G06F 3/04144; G06F 3/045; H03K 17/9625

(57) ABSTRACT

Provided is a smart sensing system using a pressure sensor, the smart sensing system including a pressure sensor configured to generate a first variable voltage and a second variable voltage by sensing a pressure that is applied; a differential amplifier configured to generate an output voltage of which a voltage value is determined based on an output current that is generated based on a voltage difference between the first variable voltage and the second variable voltage and a resistance value adjusted in response to a control signal; and a processor configured to measure the applied pressure by detecting the voltage value of the output voltage and to output the control signal used for adjusting the voltage value of an amplification voltage.

### CROSS-REFERENCE TO RELATED APPLICATION

This application claims priority to Korea Patent Application No. 10-2018-0168426, filed Dec. 24, 2018, and the entire contents thereof is incorporated by reference in its entirety.

### FIELD OF THE INVENTION

Example embodiments relate to a smart sensing system using a pressure sensor, and more particularly, to a smart sensing system using a pressure sensor that may monitor a body state of a user in real time by detecting a pressure being applied from an outside, for example, the user, and by converting a detection result to a digital signal and a waveform.

### DESCRIPTION OF THE RELATED ART

In general, a sphygmomanometer using air pressure, which is mainly used in a hospital, measures a blood pressure and a pulse by applying a pressure to a forearm in a state in which a user is stabilized to some extent. It is not recommendable to measure the blood pressure more than six times a day. The sphygmomanometer may not easily carry to measure the blood pressure. In the meantime, a smart sphygmomanometer that is not a fixed type may be carried in its own way, however, is still big and inconvenient to readily carry.

As for technology for measuring a blood pressure based on a time difference between peak values of an electrocardiography (ECG) sensor and/or a photoplethysmography (PPG) sensor, it is difficult to accurately measure the blood pressure due to various characteristics of each person.

First, the blood pressure may be measured by attaching the ECG sensor to the chest or by attaching the PPG sensor to a forearm or a wrist. That is, the blood pressure may be measured by providing two different sensors at a desired distance and by analyzing a time difference between body reactions based on an algorithm.

Second, the blood pressure may be measured at a time interval between peak values of a single pair of ECG sensors or a single pair of PPG sensors. That is, the blood pressure may be measured by providing the two same sensors at a desired distance and by analyzing a time difference between body reactions based on an algorithm.

In the related art, it may be very complex to measure the blood pressure. In particular, a minimum of two sensors need to be attached at two positions of a body separate by a desired distance and the blood pressure needs to be represented by measuring a peak value of each sensor signal. Also, for actual measurement, stabilization of the skin and a measurement electrode needs to be prioritized. An error increases based on skin tone or noise, which makes it very difficult to accurately measure the blood pressure.

### SUMMARY OF THE INVENTION

A smart sensing system using a pressure sensor according to an example embodiment includes a pressure sensor configured to generate a first variable voltage and a second variable voltage by sensing a pressure that is applied; a differential amplifier configured to generate an output voltage of which a voltage value is determined based on an output current that is generated based on a voltage difference between the first variable voltage and the second variable voltage and a resistance value that is adjusted in response to a control signal; and a processor configured to measure the applied pressure by detecting the voltage value of the output voltage and to output the control signal used for adjusting the voltage value of an application voltage.

Here, voltage values of the first variable voltage and the second variable voltage may be adjusted based on the applied pressure.

Here, the pressure sensor may include a first resistance, a second resistance, a third resistance, and a fourth resistance connected between a power source voltage and a ground voltage, and the pressure sensor may be configured to generate the first variable voltage based on resistance values of the first resistance and the second resistance that vary based on the applied pressure and to generate the second variable voltage based on resistance values of the third resistance and the fourth resistance that vary based on the applied pressure.

Here, the pressure sensor may include a first current source and a second current source, and a first capacitor and a second capacitor that are connected in series, and the pressure sensor may be configured to generate the first variable voltage based on a capacitance value of the first capacitor that varies based on the applied pressure and to generate the second variable voltage based on a capacitance value of the second capacitor that varies based on the applied pressure.

Here, the differential amplifier may be provided as a voltage-current amplifier configured to generate the output voltage of which the voltage value is determined based on the output current that is generated by detecting and amplifying the voltage difference between the first variable voltage and the second variable voltage and the resistance value.

Here, the differential amplifier may be provided as an operational amplifier (OP-AMP) configured to generate the output voltage by detecting and amplifying the voltage difference between the first variable voltage and the second variable voltage.

Here, the processor may include an analog-to-digital converter configured to generate a digital signal corresponding to the voltage value of the output voltage; and a communication circuit configured to change a logic level combination of the control signal in response to the digital signal being absent in a desired section and to output the digital signal to an external apparatus.

A smart sensing system using a pressure sensor according to another example embodiment includes a differential amplifier configured to generate an amplification voltage of which a voltage value is determined based on an output current that is generated based on a voltage difference between a first variable voltage and a second variable voltage that varies in response to a pressure being applied and a resistance value that is adjusted in response to a control signal; a voltage distribution time constant including a serial resistance and configured to output a signal of a specific frequency band of the amplification voltage based on voltage distribution using the serial resistance; a filter configured to generate an output voltage by filtering the signal of the specific frequency band included in the amplification voltage; and a processor configured to measure the applied pressure by detecting a voltage value of the output voltage and to output a digital signal corresponding to the voltage value of the output voltage to an outside.

Here, the processor may be configured to output the control signal used for adjusting the voltage value of the amplification voltage to the differential amplifier.

Here, the differential amplifier may be provided as a voltage-current amplifier configured to generate the amplification voltage of which the voltage value is determined based on the output current that is generated by detecting and amplifying the voltage difference between the first variable voltage and the second variable voltage and the resistance value.

Here, the differential amplifier may be provided as an OP-AMP configured to generate the amplification voltage by detecting and amplifying the voltage difference between the first variable voltage and the second variable voltage.

Here, the voltage distribution time constant may include a first resistance and a second resistance that are connected in series between a power source voltage and a ground voltage; and a capacitor configured to be connected between the first resistance and the second resistance and to output a signal of a specific frequency band of the amplification voltage.

Here, the processor may include an analog-to-digital converter configured to generate a digital signal corresponding to the voltage value of the output voltage; and a communication circuit configured to change and thereby output a logic level combination of the control signal in response to the digital signal being absent in a desired section and to output the digital signal to an external apparatus.

The smart sensing system using the pressure sensor may further include a pressure sensor configured to generate the first variable voltage and the second variable voltage by sensing the applied pressure.

Here, the pressure sensor may include a first resistance, a second resistance, a third resistance, and a fourth resistance connected between a power source voltage and a ground voltage, and the pressure sensor may be configured to generate the first variable voltage based on resistance values of the first resistance and the second resistance that vary based on the applied pressure and to generate the second variable voltage based on resistance values of the third resistance and the fourth resistance that vary based on the applied pressure.

Here, the pressure sensor may include a first current source and a second current source, and a first capacitor and a second capacitor that are connected in series, and the pressure sensor may be configured to generate the first variable voltage based on a capacitance value of the first capacitor that varies based on the applied pressure and to generate the second variable voltage based on a capacitance value of the second capacitor that varies based on the applied pressure.

A wearable unit to which the smart sensing system using the pressure sensor according to an example embodiment is applied may include one of a headband provided around a head of a user, a headset detachably provided around the head of the user to correct a vision of the user, to protect an eye of the user, or to assist virtual reality (VR) experience of the user, a detachable band detachably provided around an arm or a leg of the user, a headcap provided around the head of the user to protect the head of the user, and a detachable patch detachably attached at a position at which a body state of the user is to be measured.

Further areas of applicability will become apparent from the description provided herein. The description and specific examples in this summary are intended for purposes of illustration only and are not intended to limit the scope of the present disclosure.

### BRIEF DESCRIPTION OF DRAWINGS

These and/or other aspects, features, and advantages of the invention will become apparent and more readily appreciated from the following description of embodiments, taken in conjunction with the accompanying drawings of which:

FIG. 1 is a block diagram illustrating a configuration of a smart sensing system using a pressure sensor according to an example embodiment;

FIG. 2 is a block diagram illustrating an example of a configuration of a smart sensing system using a pressure sensor according to an example embodiment;

FIG. 3 is a block diagram illustrating another example of a configuration of a smart sensing system using a pressure sensor according to an example embodiment;

FIG. 4 illustrates an example of a differential amplifier of FIG. 1;

FIG. 5 illustrates an example of a voltage-current amplifier of FIGS. 2 and 3;

FIG. 6 illustrates an example of a variable resistance of FIGS. 2 and 3;

FIG. 7 is a circuit diagram illustrating a configuration of a voltage distribution time constant of FIGS. 1 to 3;

FIG. 8 is a block diagram illustrating a configuration of a smart sensing system using a pressure sensor according to another example embodiment; and

FIG. 9 illustrates various application examples of a wearable unit to which a smart sensing system using a pressure sensor according to an example embodiment is applied.

### DETAILED DESCRIPTION OF THE INVENTION

One or more example embodiments will be described with reference to the accompanying drawings. Advantages and features of the example embodiments, and methods for achieving the same may become explicit by referring to the accompanying drawings and the following example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated.

Although the terms “first,” “second,” “third,” etc., may be used herein to describe various elements, components, regions, layers, and/or sections, these elements, components, regions, layers, and/or sections, should not be limited by these terms. These terms are only used to distinguish one element, component, region, layer, or section, from another region, layer, or section. Thus, a first element, component, region, layer, or section, discussed below may be termed a second element, component, region, layer, or section, without departing from the scope of this disclosure.

Hereinafter, a smart sensing system using a pressure sensor according to example embodiments will be described with reference to the accompanying drawings. The present disclosure is not limited to or restricted by the example embodiments. Also, in the description of example embodiments, detailed description of well-known related structures or functions will be omitted when it is deemed that such description will cause ambiguous interpretation of the present disclosure.

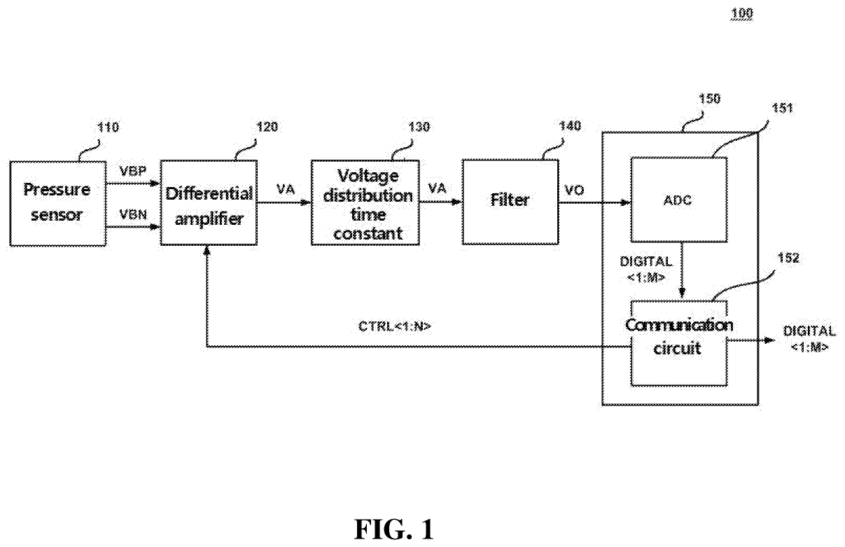

FIG. 1 is a block diagram illustrating a configuration of a smart sensing system using a pressure sensor according to an example embodiment.

Referring to FIG. 1, a smart sensing system 100 using a pressure sensor according to the example embodiment may include a pressure sensor 110, a differential amplifier 120, a voltage distribution time constant 130, a filter 140, and a processor 150.

The pressure sensor 110 may generate a first variable voltage (VBP) and a second variable voltage (VBN) by sensing a pressure that is applied from an outside. The pressure sensor 110 may generate the first variable voltage (VBP) and the second variable voltage (VBN) each of which a voltage value is adjusted based on the pressure that is applied from the outside. For example, the pressure sensor 110 may generate the first variable voltage (VBP) and the second variable voltage (VBN) such that a voltage difference therebetween may increase according to an increase in the pressure that is applied from the outside.

The differential amplifier 120 may receive the first variable voltage (VBP) and the second variable voltage (VBN) and may generate an amplification voltage (VA). The differential amplifier 120 may generate the amplification voltage (VA) of which a voltage value is determined based on an output current and a resistance value that is adjusted based on a control signal (CTRL<1:N>). Here, the output current is generated based on the voltage difference between the first variable voltage (VBP) and the second variable voltage (VBN). The differential amplifier 120 may detect and amplify the voltage difference between the first variable voltage (VBP) and the second variable voltage (VBN) and may generate the amplification voltage (VA) of which the voltage value is determined based on the resistance value.

The voltage distribution time constant 130 may output a signal of a specific frequency band of the amplification voltage (VA) based on a voltage distribution using a serial resistance included inside. The amplification voltage (VA) generated based on the voltage distribution time constant 130 may be used to detect information on the pressure that is applied from the outside. The voltage distribution time constant 130 may be configured to immediately output the amplification voltage (VA) to the processor 150 when the amplification voltage (VA) is stably generated by the differential amplifier 120.

The filter 140 may generate an output voltage (VO) by filtering the signal of the specific frequency band included in the amplification voltage (VA). The filter 140 may generate the output voltage (VO) by performing filtering of the amplification voltage (VA) that is generated through the voltage distribution time constant 130. The filter 140 may be configured to immediately output the amplification voltage (VA) to the processor 150 without performing filtering, when the amplification voltage (VA) is stably generated by the differential amplifier 120.

The processor 150 may include an analog-to-digital converter 151 and a communication circuit 152.

The analog-to-digital converter 151 may generate a digital signal (DIGITAL<1:M>) corresponding to a voltage value of the output voltage (VO). The analog-to-digital converter 151 may generate the digital signal (DIGITAL<1:M>) of which a logic level combination varies based on the voltage value of the output voltage (VO) that is an analog voltage. The analog-to-digital converter 151 may be configured as a general analog-digital converter (ADC).

The communication circuit 152 may receive the digital signal (DIGITAL<1:M>) from the analog-to-digital converter 151 and may output the same to the outside. The communication circuit 152 may output the digital signal (DIGITAL<1:M>) to the outside through a liquid crystal display (LCD). The communication circuit 152 may generate a waveform from the digital signal (DIGITAL<1:M>) and may output the waveform to the outside through the LCD. The communication circuit 152 may generate the control signal (CTRL<1:N>) used to adjust resistance values of resistances included in the differential amplifier 120. When the digital signal (DIGITAL<1:M>) is absent in a desired section, the communication circuit 152 may change the logic level combination of the control signal (CTRL<1:N>) and may output the control signal (CTRL<1:N>) with the changed logic level combination to the differential amplifier 120. When the digital signal (DIGITAL<1:M>) is absent in the desired section, it indicates that the voltage value of the output voltage (VO) is set to be significantly high or low and a significantly high or low pressure is applied accordingly. In detail, when a section of the digital signal (DIGITAL<1:M>) is higher than the desired section, it indicates that the significantly high pressure is applied. Therefore, the communication circuit 152 may change the logic level combination of the control signal (CTRL<1:N>) to decrease resistance values of the resistances included in the differential amplifier 120 and may output the control signal (CTRL<1:N>) with the changed logic level combination to the differential amplifier 120. On the contrary, when the section of the digital signal (DIGITAL<1:M>) is lower than the desired section, it indicates that the significantly low pressure is applied. Therefore, the communication circuit 152 may change the logic level combination of the control signal (CTRL<1:N>) to decrease resistance values of the resistances included in the differential amplifier 120 and may output the control signal (CTRL<1:N>) with the changed logic level combination to the differential amplifier 120.

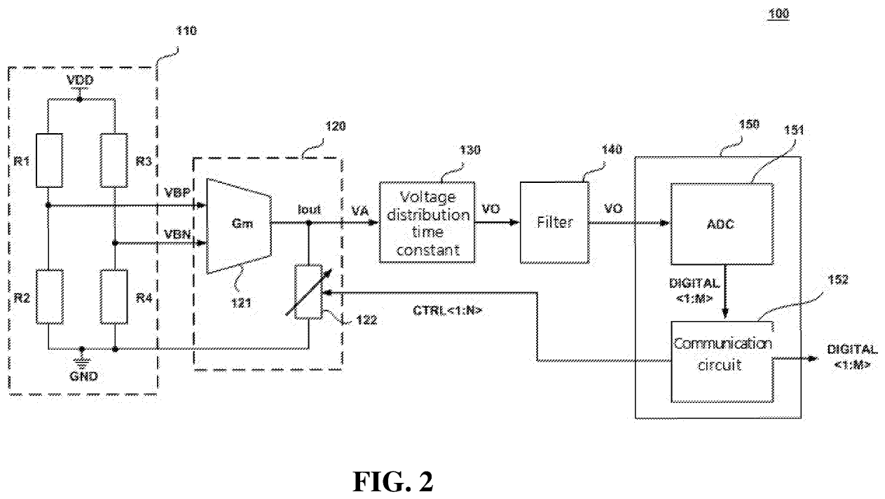

FIG. 2 is a block diagram illustrating an example of a configuration of a smart sensing system using a pressure sensor according to an example embodiment.

Referring to FIG. 2, the pressure sensor 110 of the smart sensing system 100 may be provided as a resistance-type pressure sensor that includes a plurality of resistances, for example, first to fourth resistances R1, R2, R3, and R4.

The pressure sensor 110 may generate a first variable voltage (VBP) based on the first resistance R1 and the second resistance R2 that are connected in series between a power source voltage (VDD) and a ground voltage (GND). The pressure sensor 110 may generate the first variable voltage (VBP) based on resistance values of the first resistance R1 and the second resistance R2 that vary based on a pressure that is applied from an outside. The pressure sensor 110 may generate a second variable voltage (VBN) based on the third resistance R3 and the fourth resistance R4 that are connected in series between the power source voltage (VDD) and the ground voltage (GND). The pressure sensor 110 may generate the second variable voltage (VBN) based on resistance values of the third resistance R3 and the fourth resistance R4 of which resistance values vary based on the pressure applied from the outside. The first resistance R1, the second resistance R2, the third resistance R3, and the fourth resistance R4 may be configured as variable resistances each of which a resistance value varies based on the pressure applied from the outside.

The differential amplifier 120 of the smart sensing system 100 may include a voltage-current amplifier 121 and a variable resistance 122.

The voltage-current amplifier 121 may generate an output current (Iout) that is generated by detecting and amplifying a voltage difference between the first variable voltage (VBP) and the second variable voltage (VBN). The voltage-current amplifier 121 may generate the output current (Iout) of which a current voltage varies based on the voltage difference between the first variable voltage (VBP) and the second variable voltage (VBN).

A resistance value of the variable resistance 122 may be adjusted based on a control signal (CTRL<1:N>).

That is, the differential amplifier 120 may generate an amplification voltage (VA) of which a voltage value is adjusted based on the output current (Iout) generated by the voltage-current amplifier 121 and a resistance value of the variable resistance 122. The voltage value of the amplification voltage (VA) may be set as a multiplication between the output current (Iout) and the resistance value of the variable resistance 122.

The voltage distribution time constant 130, the filter 140, and the processor 150 of FIG. 2 are configured to be identical to those of FIG. 1 and thus, a further description related thereto is omitted.

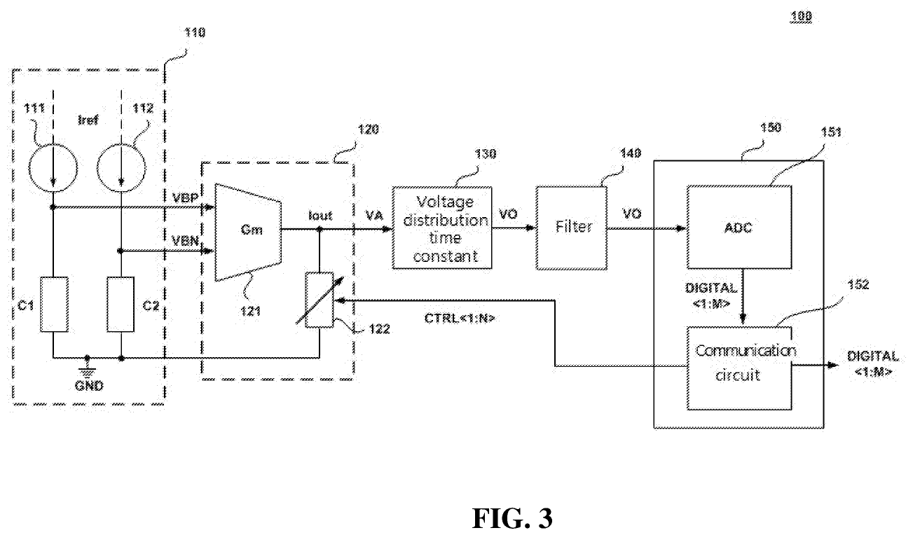

FIG. 3 is a block diagram illustrating another example of a configuration of a smart sensing system using a pressure sensor according to an example embodiment.

Referring to FIG. 3, the pressure sensor 110 of the smart sensing system 100 may be provided as a capacitor-type pressure sensor that includes a plurality of current sources, for example, first and second current sources 111 and 112, and a plurality of capacitors, for example, first and second capacitors C1 and C2.

The pressure sensor 110 may generate a first variable voltage (VBP) based on the first current source 111 and the first capacitor C1 that are connected in series. The pressure sensor 110 may generate the first variable voltage (VBP) based on the first current source 111 and the first capacitor C1 of which a capacitance value varies based on a pressured that is applied from an outside. The pressure sensor 110 may generate a second variable voltage (VBN) based on the second current source 112 and the second capacitor C2 that are connected in series. The pressure sensor 110 may generate the second variable voltage (VBN) based on the second current source 112 and the second capacitor C2 of which a capacitance value varies based on the pressure that is applied from the outside. The first capacitor C1 and the second capacitor C2 may be provided as variable capacitors each of which a capacitance value varies based on the pressure that is applied from the outside.

The differential amplifier 120 of the smart sensing system 100 may include the voltage-current amplifier 121 and the variable resistance 122.

The voltage-current amplifier 121 may generate an output current (Iout) that is generated by detecting and amplifying a voltage difference between the first variable voltage (VBP) and the second variable voltage (VBN). The voltage-current amplifier 121 may generate the output current (Iout) of which a current value varies based on the voltage difference between the first variable voltage (VBP) and the second variable voltage (VBN).

A resistance value of the variable resistance 122 may be adjusted based on a control signal (CTRL<1:N>).

That is, the differential amplifier 120 may generate an amplification voltage (VA) of which a voltage value is adjusted based on the output current (Iout) generated by the voltage-current amplifier 121 and a resistance value of the variable resistance 122. The voltage value of the amplification voltage (VA) may be set as a multiplication between the output current (Iout) and the resistance value of the variable resistance 122.

The voltage distribution time constant 130, the filter 140, and the processor 150 of FIG. 3 are configured to be identical to those of FIG. 1 and thus, a further description related thereto is omitted.

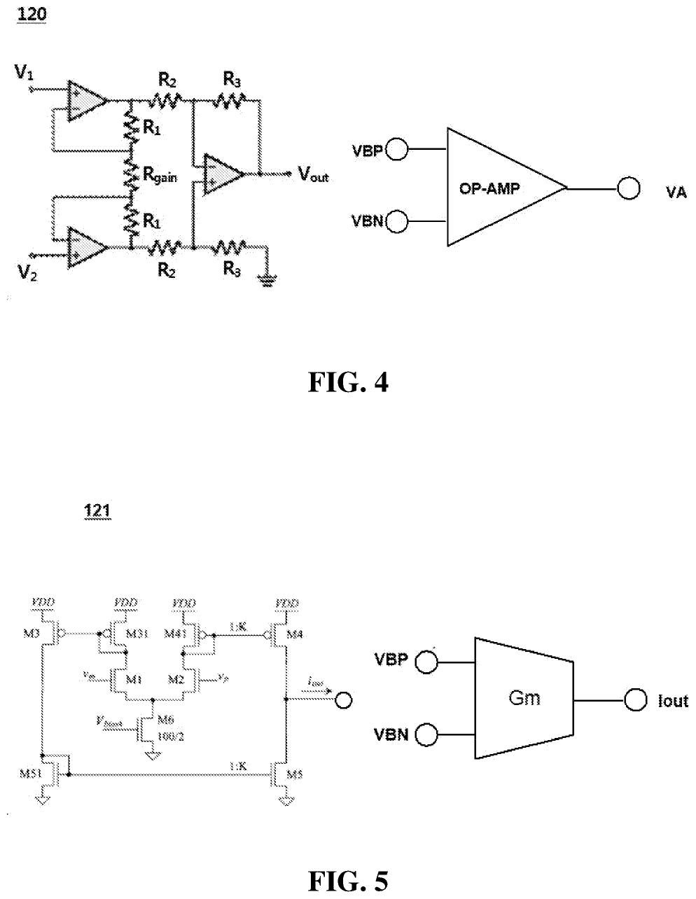

FIG. 4 illustrates an example of the differential amplifier 120 of FIG. 1.

Referring to FIG. 4, the differential amplifier 120 may be provided as an operational amplifier (OP-AMP) that includes a plurality of comparators and a plurality of resistances. The differential amplifier 120 may generate an amplification voltage (VA) by detecting a voltage difference between the first variable voltage (VBP) and the second variable voltage (VBN) and by amplifying the voltage difference.

FIG. 5 illustrates an example of the voltage-current amplifier 121 of FIGS. 2 and 3.

Referring to FIG. 5, the voltage-current amplifier 121 may include a plurality of transistors. The voltage-current amplifier 121 may adjust a current value of an output current (Iout) by detecting a voltage difference between a first variable voltage (VBP) and a second variable voltage (VBN) and by amplifying the voltage difference based on a ratio of the included transistors, for example, 1:K.

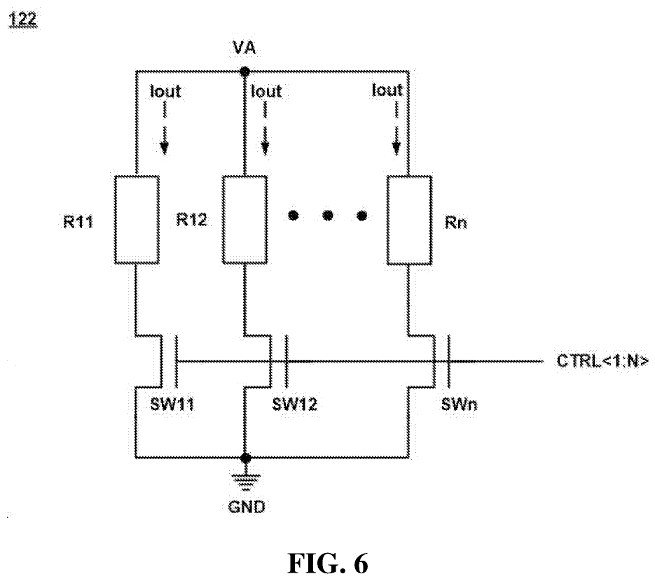

FIG. 6 illustrates an example of the variable resistance 122 of FIGS. 2 and 3.

Referring to FIG. 6, the variable resistance 122 may include a plurality of resistances (R11 to Rn) and a plurality of switches (SW11 to SWn) that are respectively connected in series between a node from which an amplification voltage (VA) is output and a ground voltage (GND). A resistance value of the variable resistance 122 may be adjusted as the plurality of switches (SW11 to SWn) is selectively turned ON based on a control signal (CTRL<1:N>). For example, when a first control signal (CTRL<1>) and a second control signal (CTRL<2>) are generated at a logic high level, a first switch SW11 and a second switch SW12 are turned ON and the resistance value of the variable resistance 122 is adjusted based on resistance values of the first resistance R11 and the second resistance R12 that are connected in parallel by the first switch SW11 and the second switch SW12. That is, the variable resistance 122 may be adjusted to have various resistance values based on the control signal (CTRL<1:N>).

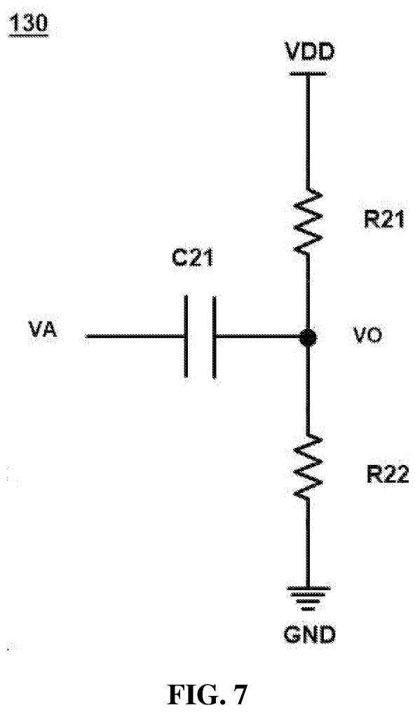

FIG. 7 is a circuit diagram illustrating a configuration of the voltage distribution time 130 according to an example embodiment.

Referring to FIG. 7, the voltage distribution time constant 130 may include a resistance R21 that is connected between a power source voltage (VDD) and a node from which an output voltage (VO) is output, a resistance R22 that is connected between the node from which the output voltage (VO) is output and a ground voltage (GND), and a capacitor C21 that is connected to the node from which the output voltage (VO) is output, and configured to receive an amplification voltage (VA) and generate the output voltage (VO). The resistance R21 and the resistance R22 that are connected in series may distribute the power source voltage (VDD), and the capacitor C21 may remove a direct current (DC) component of the amplification voltage (VA).

When a time constant of the voltage distribution time constant 130 relatively decreases, a high frequency characteristic of the output voltage (VO) that is output through the voltage distribution time constant 130 may become relatively strong. On the contrary, when the time constant of the voltage distribution time constant 130 relatively increases, the high frequency characteristic of the output voltage (VO) that is output through the voltage distribution time constant 130 may become relatively weak.

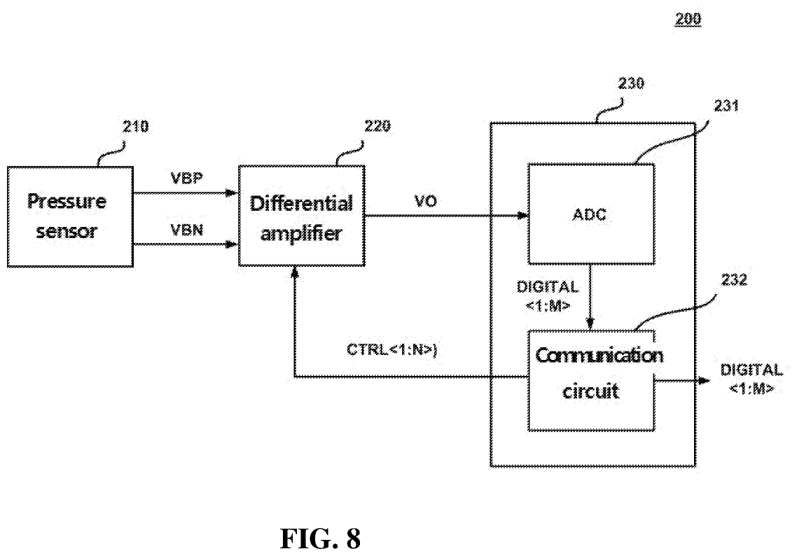

FIG. 8 is a block diagram illustrating a configuration of a smart sensing system using a pressure sensor according to another example embodiment.

Referring to FIG. 8, a smart sensing system 200 using a pressure sensor according to the example embodiment may include a pressure sensor 210, a differential amplifier 220, and a processor 230.

The pressure sensor 210 may generate a first variable voltage (VBP) and a second variable voltage (VBN) by sensing a pressure that is applied from an outside. The pressure sensor 210 may generate the first variable voltage (VBP) and second variable voltage (VBN) each of which a voltage value is adjusted based on the pressure that is applied from the outside.

For example, the pressure sensor 210 may generate the first variable voltage (VBP) and the second variable voltage (VBN) such that a voltage difference therebetween may increase according to an increase in the pressure that is applied from the outside. The pressure sensor 210 may be configured in the same circuit as that of the pressure sensor 110 of FIGS. 1 to 3 and to perform the same operation.

The differential amplifier 220 may receive the first variable voltage (VBP) and the second variable voltage (VBN) and may generate an output voltage (VO). The differential amplifier 220 may generate an output voltage (VO) of which a voltage value is determined based on an output current and a resistance value that is adjusted based on a control signal (CTRL<1:N>). Here, the output current is generated based on the voltage difference between the first variable voltage (VBP) and the second variable voltage (VBN). The differential amplifier 220 may detect and amplify the voltage difference between the first variable voltage (VBP) and the second variable voltage (VBN) and may generate the output voltage (VO) of which the voltage value is determined based on the resistance value. The differential amplifier 220 may be configured as the same circuit as that of the differential amplifier 120 of FIGS. 1 to 3.

The processor 230 may include an analog-to-digital converter 231) and a communication circuit 232.

The analog-to-digital converter 231 may generate a digital signal (DIGITAL<1:M>) corresponding to the voltage value of the output voltage (VO). The analog-to-digital converter 231 may generate the digital signal (DIGITAL<1:M>) of which a logic level combination varies based on the voltage value of the output voltage (VO) that is an analog voltage. The analog-to-digital converter 231 may be configured as a general analog-digital converter (ADC).

The communication circuit 232 may receive the digital signal (DIGITAL<1:M>) from the analog-to-digital converter 231 and may output the same to the outside. The communication circuit 232 may output the digital signal (DIGITAL<1:M>) to the outside through an LCD. The communication circuit 232 may generate a waveform from the digital signal (DIGITAL<1:M>) and may output the waveform to the outside through the LCD. The communication circuit 232 may generate a control signal (CTRL<1:N>) used to adjust resistance values of resistances included in the differential amplifier 220. When the digital signal (DIGITAL<1:M>) is absent in a desired section, the communication circuit 232 may change the logic level combination of the control signal (CTRL<1:N>) and may output the control signal (CTRL<1:N>) with the changed logic level combination to the differential amplifier 220. When the digital signal (DIGITAL<1:M>) is absent in the desired section, it indicates that the voltage value of the output voltage (VO) is set to be significantly high or low and a significantly high or low pressure is applied accordingly. In detail, when a section of the digital signal (DIGITAL<1:M>) is higher than the desired section, it indicates that the significantly high pressure is applied. Therefore, the communication circuit 232 may change the logic level combination of the control signal (CTRL<1:N>) to decrease resistance values of the resistances included in the differential amplifier 220 and may output the control signal (CTRL<1:N>) with the changed logic level combination to the differential amplifier 220. On the contrary, when the section of the digital signal (DIGITAL<1:M>) is lower than the desired section, it indicates that the significantly low pressure is applied. Therefore, the communication circuit 232 may change the logic level combination of the control signal (CTRL<1:N>) to decrease resistance values of the resistances included in the differential amplifier 220 and may output the control signal (CTRL<1:N>) with the changed logic level combination to the differential amplifier 220.

As described above, a smart sensing system using a pressure sensor according to example embodiments may monitor a body state of a user in real time by detecting a pressure applied from an outside, for example, the user and by converting a detection result to a digital signal and a waveform.

Also, according to example embodiments, the smart sensing system using the pressure sensor may be implemented using a relatively small area by further simplifying a detailed configuration of a differential amplifier.

Also, according to example embodiments, the smart sensing system using the pressure sensor may verify a body state of a user in real time in response to a selection of the user. In particular, the smart sensing system may extract body information corresponding to various body states of the user based on a pressure applied from an outside, for example, the user, through a detailed configuration of the smart sensing system and to provide the extracted body information to the user.

Also, according to example embodiments, the smart sensing system using the pressure sensor may conveniently and accurately measure at least one of a body temperature, a blood pressure, a blood flow, and oxygen saturation.

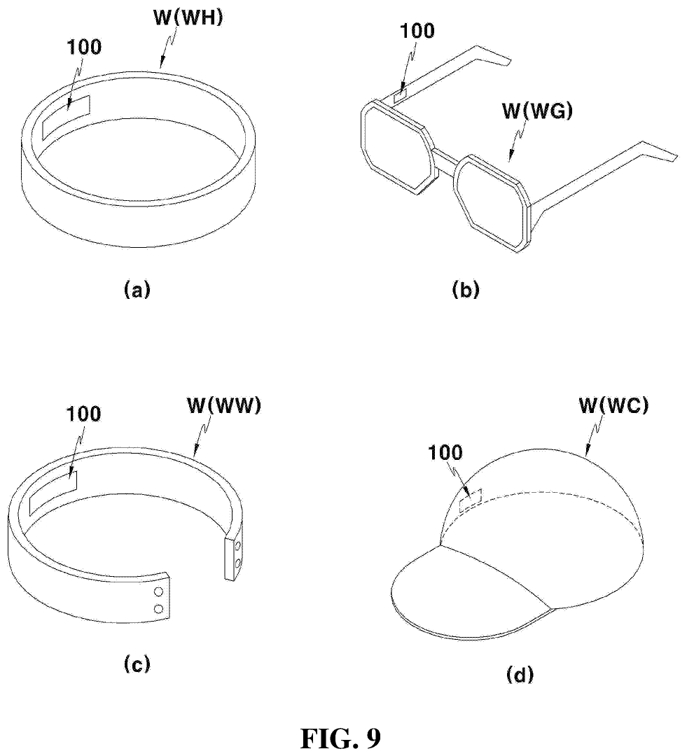

FIG. 9 illustrates various application examples of a wearable unit to which a smart sensing system using a pressure sensor according to an example embodiment is applied.

Referring to FIG. 9, the smart sensing system 100 using a pressure sensor is provided on a surface on which a wearable unit (W) is to contact a body of a user.

Here, the wearable unit (W) may include one of a headband (WH) provided around a head of the user, a headset (WG) detachably provided around the head of the user to correct a vision of the user, to protect an eye of the user, or to assist virtual reality (VR) experience of the user, a detachable band (WW) detachably provided around an arm or a leg of the user, a headcap (WC) provided around the head of the user to protect the head of the user, and a detachable patch (not shown) detachably attached at a position at which a body state of the user is to be measured.

Here, the headband (WH) has elasticity and thus, may enhance a force of adhesion between the smart sensing system 100 and a body of the user. The headband (WH) may be stably provided around the head of the user along the circumference thereof and thereby supported by the head of the user. Referring to (a) of FIG. 9, the smart sensing system 100 using the pressure sensor may be provided on an inner surface of the headband (WH) to be positioned at the temple of the user.

Also, the headset (WG) may be provided as, for example, glasses, goggles, and a headset for VR experience. Referring to (b) of FIG. 9, when the headset (WG) is provided as glasses, the smart sensing system 100 using the pressure sensor may be provided to a frame of the glasses to correspond to the temple of the head of the user. When the headset (WG) is provided as goggles or the headset for VR experience, the smart sensing system 100 may be provided to a goggle frame or a headset frame, may be provided to a goggle leg or a goggle band for supporting the goggle frame, or may be provided to a headset band for supporting a headset frame. The goggle band or the headset band has elasticity and thus, may enhance a force of adhesion between the smart sensing system 100 and the body of the user.

Also, the detachable band (WW) has elasticity and thus, may enhance a force of adhesion between the smart sensing system 100 and the body of the user. The detachable band (WW) may be provided around an arm or a leg of the user along the circumference thereof and thereby stably supported by the arm or the leg of the user. A detachable coupler is provided at each of both ends of the detachable band (WW) and enables the detachable band (WW) to be conveniently detached from or attached to the body of the user. Referring to (c) of FIG. 9, the smart sensing system 100 using the pressure sensor may be provided on an inner surface of the detachable band (WW) to be in contact with a wrist of the user or an ankle of the user. The blood pressure may be measured by measuring a wavelength of blood flowing in the blood vessel, that is, may be calculated by measuring a pressure P2 against which the blood vessel repulsively rebounds against a pressure P1 that presses the blood vessel when the detachable band (WW) having the elasticity presses the wrist. Also, the reliability of blood pressure measurement using the wearable unit (W) may be further enhanced by additionally providing specific individual body information, such as a height and a weight, and a normalized blood pressure range.

Also, the headcap (WC) may be provided as, for example, a cap and a helmet. When the headcap (WC) is provided as the cap, an elastic cap band may be provided at inner edge of a cap portion that surrounds the head of the user. When the headcap (WC) is provided as the helmet, a helmet band that wraps around the head of the user may be provided at inner edge of the helmet. Referring to (d) of FIG. 9, when the headcap (WC) is provided as the cap, the smart sensing system 100 using the pressure sensor may be provided on an inner side of the headcap (WC) to correspond to the temple of the head of the user.

Also, the detachable patch (not shown) has elasticity and thus, may enhance a force of adhesion between the smart sensing system 100 and the user.

As described above, a wearable unit to which a smart sensing system using a pressure sensor according to example embodiments is applied may monitor a body state of a user by detecting a pressure applied from an outside, for example, the user, and by converting a detection result to a digital signal.

A number of example embodiments have been described above. Nevertheless, it should be understood that various modifications may be made to these example embodiments. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A smart sensing system using a pressure sensor, the smart sensing system comprising:
a pressure sensor configured to generate a first variable voltage and a second variable voltage by sensing a pressure that is applied;
a differential amplifier configured to generate an output voltage of which a voltage value is determined based on an output current that is generated based on a voltage difference between the first variable voltage and the second variable voltage and a resistance value that is adjusted based on a control signal; and
a processor configured to measure the applied pressure by detecting the voltage value of the output voltage and to output the control signal used for adjusting the voltage value of an amplification voltage.

2. The smart sensing system of claim 1, wherein voltage values of the first variable voltage and the second variable voltage are adjusted based on the applied pressure.

3. The smart sensing system of claim 1, wherein the pressure sensor comprises a first resistance, a second resistance, a third resistance, and a fourth resistance connected between a power source voltage and a ground voltage, and
the pressure sensor is configured to generate the first variable voltage based on resistance values of the first resistance and the second resistance that vary based on the applied pressure and to generate the second variable voltage based on resistance values of the third resistance and the fourth resistance that vary based on the applied pressure.

4. The smart sensing system of claim 1, wherein the pressure sensor comprises a first current source and a second current source, and a first capacitor and a second capacitor that are connected in series, and
the pressure sensor is configured to generate the first variable voltage based on a capacitance value of the first capacitor that varies based on the applied pressure and to generate the second variable voltage based on a capacitance value of the second capacitor that varies based on the applied pressure.

5. The smart sensing system of claim 1, wherein the differential amplifier is provided as a voltage-current amplifier configured to generate the output voltage of which the voltage value is determined based on the output current that is generated by detecting and amplifying the voltage difference between the first variable voltage and the second variable voltage and the resistance value.

6. The smart sensing system of claim 1, wherein the differential amplifier is provided as an operational amplifier (OP-AMP) configured to generate the output voltage by detecting and amplifying the voltage difference between the first variable voltage and the second variable voltage.

7. The smart sensing system of claim 1, wherein the processor comprises:
an analog-to-digital converter configured to generate a digital signal corresponding to the voltage value of the output voltage; and
a communication circuit configured to change a logic level combination of the control signal in response to the digital signal being absent in a desired section and to output the digital signal to an external apparatus.

8. A smart sensing system using a pressure sensor, the smart sensing system comprising:
a differential amplifier configured to generate an amplification voltage of which a voltage value is determined based on an output current that is generated based on a voltage difference between a first variable voltage and a second variable voltage that varies in response to a pressure being applied and a resistance value that is adjusted in response to a control signal;
a voltage distribution time constant comprising a serial resistance and configured to output a signal of a specific frequency band of the amplification voltage based on voltage distribution using the serial resistance;
a filter configured to generate an output voltage by filtering the signal of the specific frequency band included in the amplification voltage; and
a processor configured to measure the applied pressure by detecting a voltage value of the output voltage and to output a digital signal corresponding to the voltage value of the output voltage to an outside.

9. A wearable unit to which the smart sensing system using the pressure sensor of claim 1 is applied.

10. The wearable unit of claim 9, comprising one of a headband provided around a head of a user, a headset detachably provided around the head of the user to correct a vision of the user, to protect an eye of the user, or to assist virtual reality (VR) experience of the user, a detachable band detachably provided around an arm or a leg of the user, a headcap provided around the head of the user to protect the head of the user, and a detachable patch detachably attached at a position at which a body state of the user is to be measured.
